(19) United States
(12) Patent Application Publication
(10) Pub. No.: US 2025/0066185 A1
(43) Pub. Date: Feb. 27, 2025

(54) COUPLING DEVICE FOR COUPLING VIBRATION SYSTEMS

(71) Applicant: Northrop Grumman Litef GmbH, Freiburg (DE)

(72) Inventor: Jan Daniel RENDE, Freisen-Reitscheid (DE)

(21) Appl. No.: 18/721,708

(22) PCT Filed: Nov. 16, 2022
(86) PCT No.: PCT/EP2022/082119

§ 371 Date: Jun. 19, 2024

(30) Foreign Application Priority Data
Dec. 22, 2021 (DE) 10 2021 134 351.8

(51) Int. Cl. B81B 3/00

(52) U.S. Cl. CPC B81B 3/0059; B81B 2201/025; B81B 2203/0163; B81B 2203/051

(57) ABSTRACT

A coupling device (100) for coupling two vibration systems (210, 220), which are mounted over a substrate such that the vibration systems are linearly arranged along a first direction (x) and can vibrate along the first direction (x), has a closed spring structure (110), which can be connected to the vibration systems (210, 220) at outer faces lying opposite each other along the first direction (x), and an anchor structure (120), which is rigidly connected to the substrate and which is arranged within the closed spring structure (110) and is connected to the spring structure (110) at two inner faces lying opposite each other along a second direction (y) that is orthogonal to the first direction. In this manner, the coupling device (100) connected to the vibration systems (210, 220) imparts a differential-mode coupling to the vibration systems (210, 220) as the mode with the lowest frequency.

The present invention relates to coupling devices for coupling two vibration systems and micro-electro-mechanical components, such as inertial sensors, angular rate sensors and the like, that have two coupled vibration systems.

In micro-electro-mechanical systems (MEMS) such as inertial sensors or gyroscopes, there is often a technical need to have masses vibrate in push-pull mode, for example, to create a force and torque-free system. If both masses are on a line of movement, then spring mechanisms are often used which can impart coupling for synchronized vibration of both masses (common mode) or vibration of both masses in the opposite direction (push-pull mode).

The common mode essentially corresponds to a non-utilization of the spring mechanism. A spring stiffness allocated to the common mode is therefore less than a spring stiffness allocated to the push-pull mode. Based on the relationship for the natural frequency ω=√k/m (k: spring stiffness, m: mass), it follows that the natural frequency/resonance frequency ω for the common mode is, as a rule, lower than the natural frequency/resonance frequency for the push-pull mode.

Usually, however, push-pull coupling is necessary for the advantageous design of the function of the MEMS. It is therefore the object of the present invention to specify a coupling device and a micro-electro-mechanical component including the coupling device, for which push-pull coupling is not energetically disadvantaged compared to common-mode coupling.

This object is achieved by the subject matter of the independent claims.

A coupling device for coupling two vibration systems, which are mounted above a substrate such that the vibration systems are linearly arranged along a first direction and can vibrate along the first direction, includes a closed spring structure which can be connected to the vibration systems on outer faces opposite each other along the first direction, and an anchor structure, which is rigidly connected to the substrate and which is arranged within the closed spring structure and is connected to the spring structure on two inner faces opposite each other along a second direction that is orthogonal to the first direction. In this process, the coupling device that is connected to the vibration systems imparts push-pull coupling of the vibration systems as the mode with the lowest frequency.

A closed spring structure, i.e., an essentially linear, deformable structure that has no open ends (and can therefore be topologically deformed into a circle), to which only two vibration systems are connected, performs vibration, in which the two vibration systems are guided in common mode, as the lowest vibration mode, i.e., as the mode with the lowest vibration frequency. This vibration mode is suppressed if the spring structure is connected to the substrate via two points, the connecting line of which is perpendicular to the vibration direction of the vibration systems or the connecting line of which is between the connections of the spring structure to the vibration systems. This connection ensures that at least the same amount of energy must be used for displacement of the two vibration systems in the same direction as for displacement in the opposite direction. By designing the anchor(s) of the spring structure within the spring structure, this can be achieved in a space-saving manner.

The spring structure can be configured symmetrically at least with respect to two axes of symmetry that are perpendicular to each other. The two vibration systems can be connected to the spring structure along the first axis of symmetry, and the two connections of the spring structure to the anchor structure can lie along the second axis of symmetry. The symmetrical design of the spring structure makes it easier to determine possible deflections, i.e., the eigenmodes and their excitation energies. In addition, equal forces on the two vibration systems lead to equal deflections if the spring structure is configured symmetrically.

In so doing, the spring structure can deform in the opposite direction to the same extent along the second axis of symmetry when deformed along the first axis of symmetry. This means that a deflection of the vibration systems by a certain amount leads to a deformation of the spring structure along the first axis of symmetry, which is accompanied by a deformation of the spring structure along the second axis of symmetry, the deflection of which is in relation to the amount of deflection of the vibration systems (e.g., proportional or equal to it). This deformation makes coupling to the push-pull mode “softer” than coupling to the common mode, i.e., the spring constant that can be allocated to the push-pull mode becomes less than the spring constant that can be allocated to the common mode. As a result, the natural frequency of the push-pull mode becomes less than that of the common mode, whereby the push-pull mode becomes more energetically favorable than the common mode.

Furthermore, the coupling device can have first spring elements that connect the anchor structure to the spring structure. In this case, the first spring elements can essentially only be deflected along the second direction. The connection of the spring structure to the substrate is therefore again provided via bendable or deformable elements, e.g., via a double-folded bending beam spring. This means that the points at which the spring structure is connected to the substrate do not have to be fixed if the spring structure is deformed, but can vibrate along the second direction, i.e., perpendicular to the direction of vibration of the vibration systems. This enables the formation of eigenmodes that impart a push-pull mode of the vibration systems and have a lower natural frequency/are energetically more favorable than modes that lead to a common mode.

Furthermore, the coupling device can have second spring elements via which the vibration systems can be connected to the spring structure. In this case, the second spring elements can essentially only be deflected along the first direction. The second spring elements thus serve to simplify the coupling of the vibration systems to the spring structure. Due to the second spring elements, the vibration behavior of the spring structure can be made even more flexible, since a rigid coupling of the spring structure and vibration systems is omitted, which requires a slavish synchronization of the corresponding parts of the spring structure with the vibration systems.

The anchor structure can be configured as a single anchor lying in the center of the spring structure. This means that there is only one connection point via which the spring structure is connected to the substrate. This can be advantageous from a manufacturing point of view. In addition, a single connection to the substrate allows a larger number of different vibration modes, whereby the coupling device can be used in a variety of applications.

However, the anchor structure can also include two (or more) anchors that are arranged on the first axis of symmetry, i.e., on the direction of vibration of the two vibration systems. Rotational movements of the spring structure, in particular, can thereby be suppressed. However, the plurality of anchors can also be arranged along the second axis of symmetry.

The spring structure can be configured in a circular, rectangular, square, hexagonal, elliptical or diamond-shaped manner. This simplifies the manufacture of the spring structure.

If the spring structure is configured in a rectangular, square or hexagonal manner, the connections to the two vibration systems and to the anchor structure can be designed on the sides of the rectangle, the square or the hexagon, respectively. In case that the spring structure is configured in a square, diamond-shaped or hexagonal manner, the connections to the two vibration systems and to the anchor structure can be configured in the corners of the square, the diamond or the hexagon, respectively. This type of symmetrical coupling improves the vibration behavior of the coupling structure and ensures that the common mode is no longer preferred.

A micro-electro-mechanical component can include the coupling device as described above and the two vibration systems that are connected to the spring structure of the coupling device. In such a micro-electro-mechanical component, the advantages described above can be achieved.

The invention will be described in detail in the following text, with reference to the figures. The description and figures are purely exemplary. The invention is defined solely by the claims.

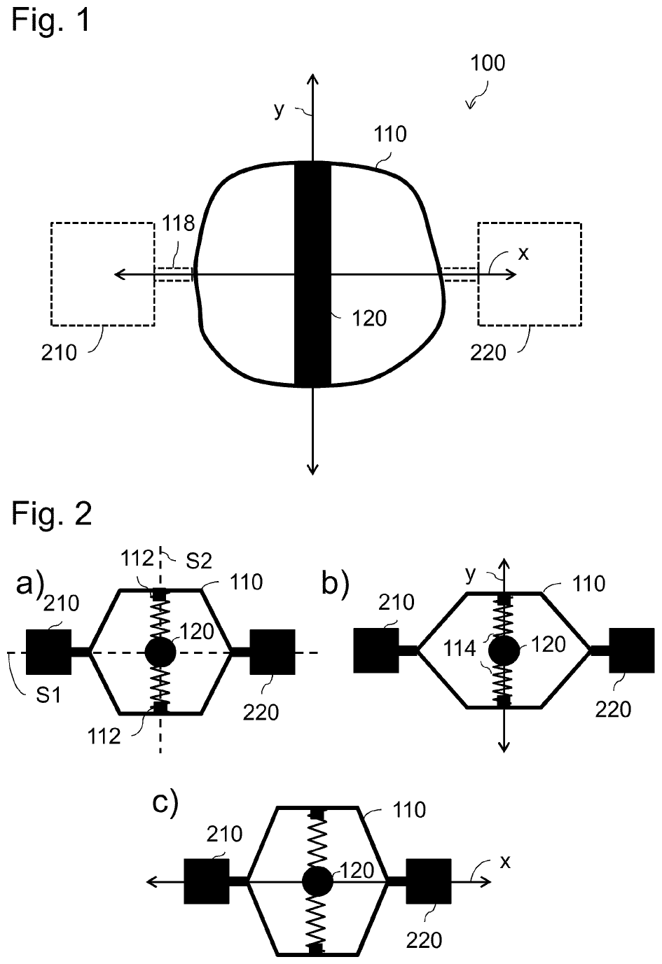

FIG. 1 shows a schematic diagram of a coupling device;

FIG. 2 shows a schematic diagram of another coupling device;

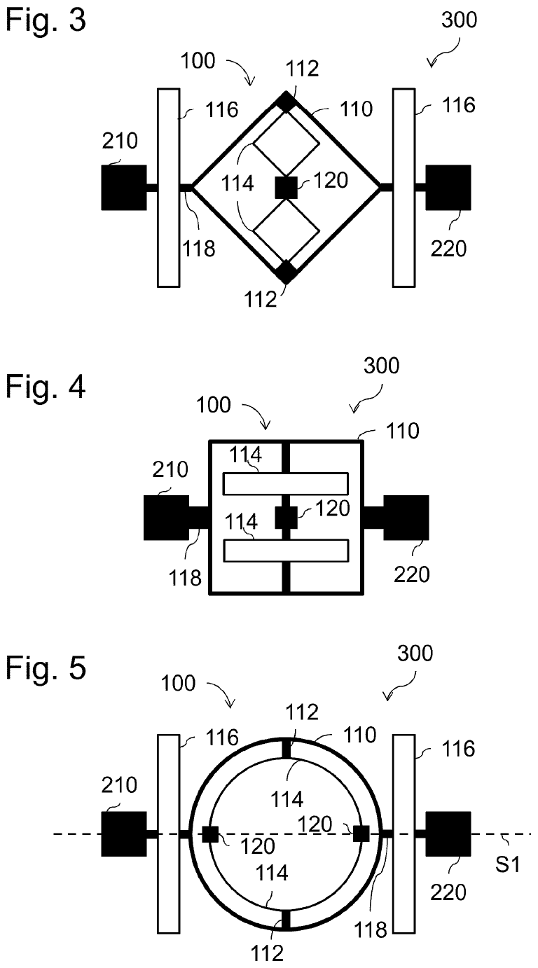

FIG. 3 shows a schematic diagram of a micro-electro-mechanical component with a coupling device;

FIG. 4 shows a schematic diagram of another micro-electro-mechanical component with a coupling device; and

FIG. 5 shows a schematic diagram of another micro-electro-mechanical component with a coupling device.

FIG. 1 shows a schematic diagram of a coupling device 100 for coupling two vibration systems 210, 220. The vibration systems 210, 220 can be part of a micro-electro-mechanical component or a micro-electro-mechanical system, MEMS, such as an inertial sensor or an angular rate sensor. The vibration systems 210, 220 are arranged along a first direction x and can vibrate along this direction over a substrate (in FIG. 1 imagined underneath the components as depicted). The vibration systems 210, 220 can have any complexity and, in particular, consist of a plurality of masses and springs which can perform a wide variety of movements relative to the substrate. However, the decisive factor here is that the vibration systems 210, 220, viewed as a whole, lie on the line defined by the first direction x and can perform vibrations along this direction.

The coupling device 100 is designed such that (in case of connected vibration systems 210, 220) it preferably forces the vibration systems 210, 220 to vibrate in push-pull mode, i.e., that the excitation mode of the push-pull vibration is energetically preferred or has a lower natural frequency than the common mode vibration.

For this purpose, the coupling device 100 has a closed spring structure 110. In this case, the term “closed” means that the spring structure is topologically a ring, i.e., that it can be mentally deformed into a ring without severing it. Otherwise, the form of the spring structure 110 is arbitrary as long as it can perform the functions described below. In particular, the spring structure 110 can principally also have an irregular contour, as shown in FIG. 1. In addition to the closed contour, the spring structure 110 can additionally also include components that protrude from this contour, such as springs, coupling points or the like.

The spring structure 110 consists of a flexible material that can be deformed parallel to the substrate plane (i.e., parallel to the image plane of FIG. 1). For example, the spring structure can be configured as a web forming a closed bending beam spring, which is exposed during the production of a MEMS. This allows the spring structure 110 to impart movements in the first direction x through corresponding deformation.

The vibration systems 210, 220 are connected to the spring structure 110 via corresponding connections 118 on the outer face of the spring structure 110. The connections 118 of the vibration systems 210, 220 to the spring structure 110 lie preferably opposite each other on the line defined by the first direction x, i.e., they are preferably not offset along a second direction y that is perpendicular to the first direction x. However, if the spring structure 110 is designed accordingly, it can also be possible to couple the vibration systems 210, 220 with an offset along the second direction y.

An otherwise free-floating spring structure 110, which is only connected to the vibration systems 210, 220, will impart a common mode of the vibration systems 210, 220 as the lowest vibration mode. In this case, the spring structure 110 essentially performs the same vibration without any deformation as the vibration systems 210, 220 vibrating in the common mode. Vibration in the push-pull mode will then only occur under certain excitation conditions.

In order to prevent this, the coupling device 100 includes an anchor structure 120 which connects the spring structure 110 to the substrate. The anchor structure 120 is, in this case, connected to the inner face of the spring structure 110 at two points opposite each other along the second direction y, i.e., the anchor structure 120 is designed in the area surrounded by the spring structure 110. By connecting the spring structure 110 at two points the connecting line of which is perpendicular to the vibration direction of the two vibration systems 210, 220, common mode coupling becomes energetically less favorable, since free displacement of the spring structure 110 is no longer possible, i.e., the natural frequency increases. The energy level of common-mode coupling is raised or preferably brought above the level of the push-pull coupling, at least up to the energetic degeneration with the push-pull coupling.

In the simplest case, the connection of the spring structure 110 to the substrate consists of a direct connection to the substrate, as indicated in FIG. 1. This leads to an energetic degeneration of the common mode and push-pull mode, since the movements of the spring structure on both sides of the connection to the substrate no longer have any influence on the movements on the other side, i.e., vibration of both sides in phase is energetically equivalent to vibration in the opposite phase.

Preferably, however, the connection of the spring structure 110 to the substrate is implemented indirectly, e.g., via first spring elements 114 which extend from connections 112 on the spring structure to an anchor of the anchor structure 120 which is rigidly connected to the substrate. This is explained in more detail with reference to FIG. 2.

FIGS. 2a) to c) show a coupling device 100 which is connected to two vibration systems 210, 220. The coupling device 100 therein has first spring elements 114, which are coupled to the (for example, hexagonally configured) spring structure 110 via connections 112 and thus connect the spring structure 110 to the anchor structure 120 lying within the spring structure 110. The configuration of the first spring elements 114 depicted in FIG. 2 is to be understood as purely schematic in that a common pictogram for a spring is depicted. The first spring elements 114 can assume any form that is suitable for use in a MEMS.

As shown in FIG. 2, the first spring elements 114 of the spring structure 110 allow themselves to be stretched and compressed along the second direction y. For this purpose, the first spring elements 114 can essentially only be deformable along the second direction. FIG. 2a) shows the rest position, FIG. 2b) compression along the second direction y, and FIG. 2c) an elongation along the second direction y. In this process, the deformation of the spring structure 110 in the second direction y occurs in the opposite direction to the deformation along the first direction x, which imparts coupling of the vibration systems 210, 220. In addition, the deformations can be in relation to each other, i.e., the amount of deformation in one direction can correspond to the deformation in the other direction. For example, the amount of deflection in the first direction x can be proportional or equal to the amount of deflection in the second direction y (with signs of deflection being reversed).

The deformations of the coupling device 100 and its components that occur in the push-pull coupling are, in this case, lower than in case that the vibration systems 210, 220 would vibrate in the common mode. As a result, the push-pull mode has a lower natural frequency and is energetically more favorable than the common mode.

This can be additionally supported by the symmetrical design of the coupling device 100 or the spring structure 110, shown in FIG. 2. As shown in FIG. 2, the coupling device 100 can be configured symmetrically at least with respect to two axes of symmetry S1, S2. The first axis of symmetry S1 runs, in this case, along the first direction x. The connections 118 of the spring structure 110 to the vibration systems 210, 220 are arranged thereon. The second axis of symmetry runs along the second direction y. The connections 112 of the spring structure 110 to the anchor structure 120, which in the example of FIG. 2 are provided by the first spring elements 114, are arranged thereon.

The symmetrical design of the coupling device 100 improves the deflection dynamics of the coupling device 100, since symmetrical deformations are energetically favored, which automatically impart a movement of the two vibration systems 210, 220 along the first direction x. However, the symmetrical design is not mandatory. If the vibration systems 210, 220 are configured accordingly, e.g., by using deflection springs or the like, spring structures 110 that are not configured symmetrically can also be advantageous.

The coupling device 100 or at least the spring structure 110 can also be configured symmetrically with respect to more than the two axes of symmetry S1, S2 discussed above. For example, the spring structure 110 of FIG. 2 has a hexagonal form which (in the rest position) is symmetrical with respect to all side bisectors and all angle bisectors. The spring structure 110 (in the rest position) can, in particular, be configured in a circular, elliptical, rectangular, square or diamond-shaped manner. In addition, the first spring elements 114 can also act on other points of the spring structure 110 in order to transfer (part of) the symmetries of the spring structure 114 to the entire coupling device 100. However, for the improved guidance of the vibration systems 210, 220 described above, it is crucial here that any deformation of the coupling device 100 or the spring structure 110 is always symmetrical with respect to the two axes of symmetry S1, S2 running along the first direction x and the second direction y.

FIGS. 3 to 5 depict in an exemplary and schematic manner various embodiments of micro-electro-mechanical components 300 which include a coupling device 100 and the two vibration systems 210, 220. It goes without saying that any number of otherwise configured micro-electro-mechanical components 300 is possible, in which various of the explicitly described or depicted elements are combined.

FIG. 3 shows a micro-electro-mechanical component 300 in which the two vibration systems 210, 220 are, by means of second spring elements 116, coupled to a diamond-shaped spring structure 110, at the center of which is a single anchor structure which is connected to the spring structure 110 via two diamond-shaped bending beam springs constituting the first spring elements 114.

The second spring elements 116 are, in this case, depicted as double-folded bending beam springs, which eliminate a strict relationship between the movement of the vibration systems 210, 220 and the deformation of the spring structure 110. It goes without saying that spring designs other than the second spring elements 116 can also be used to fulfill this function. In particular, all springs that can essentially only be deformed along the first direction x can be used.

As a further example, FIG. 4 shows a rectangular spring structure 110, which is connected to the centrally lying anchor structure 120 via two double-folded bending beam springs.

A design as sketched in FIG. 5 is also conceivable. An anchor structure 120 consisting of two anchors, which are arranged along the first axis of symmetry S1, i.e., along the first direction x, is used therein. These anchors are connected to the spring structure 110 by first spring elements 114 designed as arcuate bending beam springs together with the connections 112 arranged along the second axis of symmetry S2. By using such a structure, the coupling device 100 can be stabilized with respect to rotational movements in the substrate plane (i.e., the image plane of FIG. 5).

The coupling devices 100 described above have in common that they include an anchor structure 120, which lies within the spring structure 110 that imparts the push-pull mode. This makes the coupling device 100 particularly compact and is therefore suitable for space-saving provision of push-pull vibrations in micro-electro-mechanical systems.

1-10. (canceled)

11. A coupling device for coupling two vibration systems, which are mounted above a substrate such that the vibration systems are linearly arranged along a first direction and can vibrate along the first direction, including:
a closed spring structure, which can be connected to the vibration systems on outer faces opposite each other along the first direction;
an anchor structure, which is rigidly connected to the substrate and which is arranged within the closed spring structure and is connected to the spring structure on two inner faces opposite each other along a second direction that is orthogonal to the first direction; wherein
the coupling device connected to the vibration systems imparts push-pull coupling of the vibration systems as the mode with the lowest frequency; and
the anchor structure is configured as a single anchor lying in the center of the spring structure, or
the anchor structure includes two anchors which are arranged on the first axis of symmetry.

12. The coupling device according to claim 11, wherein
the spring structure is configured symmetrically at least with respect to two axes of symmetry that are perpendicular to each other;
the two vibration systems can be connected to the spring structure along the first axis of symmetry; and
the two connections of the spring structure to the anchor structure lie along the second axis of symmetry.

13. The coupling device according to claim 12, wherein
the spring structure deforms in the opposite direction to the same extent along the second axis of symmetry when deformed along the first axis of symmetry.

14. The coupling device according to claim 11, further comprising:
first spring elements which connect the anchor structure to the spring structure; wherein
the first spring elements can essentially only be deflected along the second direction.

15. The coupling device according to claim 11, further comprising:
second spring elements via which the vibration systems can be connected to the spring structure; wherein
the second spring elements can essentially only be deflected along the first direction.

16. The coupling device according to claim 11, wherein
the spring structure is configured in a circular, rectangular, square, hexagonal, elliptical or diamond-shaped manner.

17. The coupling device according to claim 16, wherein
the spring structure is configured in a rectangular, square or hexagonal manner, and the connections to the two vibration systems and to the anchor structure are designed on the sides of the rectangle, the square or the hexagon, respectively; or
the spring structure is configured in a square, diamond-shaped or hexagonal manner, and the connections to the two vibration systems and to the anchor structure are configured in the corners of the square, the diamond or the hexagon, respectively.

18. A micro-electro-mechanical component, including:
the coupling device according to claim 11; and
the two vibration systems which are connected to the spring structure of the coupling device.
